(19) United States
(12) Patent Application Publication
(10) Pub. No.: US 2024/0337697 A1
(43) Pub. Date: Oct. 10, 2024

(54) SYSTEMS AND METHODS FOR MONITORING A LOCATION OF A BATTERY WITHIN A BATTERY STACK

(71) Applicant: Ford Global Technologies, LLC, Dearborn, MI (US)

(72) Inventors: Sam Hoff, Hazel Park, MI (US); Vikas Rajendra, Novi, MI (US)

(73) Assignee: Ford Global Technologies, LLC, Dearborn, MI (US)

(21) Appl. No.: 18/295,296

(22) Filed: Apr. 4, 2023

(51) Int. Cl. G01R 31/371; G01R 31/396; H04L 67/12

(52) U.S. Cl. CPC G01R 31/371; G01R 31/396; H04L 67/12

(57) ABSTRACT

A method includes determining, by a battery controller, whether a battery connection condition of a given battery from among a plurality of batteries disposed within a battery stack is satisfied; generating, by the battery controller, a connection indication signal associated with the given battery in response to the battery connection condition being satisfied; transmitting, by the battery controller, the connection indication signal and battery identification information associated with the given battery to a battery stack controller using a wired communication protocol; transmitting, by the battery stack controller, the connection indication signal and the battery identification information to a central controller using a wireless communication protocol; monitoring, by the central controller, a location of the given battery based on the connection indication signal and the battery identification information; and controlling, by the central controller, an operation of a robot based on the location of the given battery.

### FIELD

The present disclosure relates to systems and methods for monitoring a location of a battery within a battery stack.

### BACKGROUND

The statements in this section merely provide background information related to the present disclosure and may not constitute prior art.

Modular and swappable batteries may be employed by one or more autonomous robots in a manufacturing environment to, for example, perform autonomous-based propulsion routines. The autonomous robots may retrieve batteries from a charging station when one or more onboard batteries disposed thereon have an amount of power that is below a threshold power level, and the autonomous robots may position the one or more onboard batteries within the charging station to charge the onboard batteries. However, locating and tracking the batteries within a stack of batteries and/or connections or disconnections therebetween is a time and resource intensive task. These issues with locating and tracking batteries within a battery stack, among other issues, are addressed by the present disclosure.

### SUMMARY

This section provides a general summary of the disclosure and is not a comprehensive disclosure of its full scope or all of its features.

The present disclosure provides a method including determining, by a battery controller, whether a battery connection condition of a given battery from among a plurality of batteries disposed within a battery stack is satisfied; generating, by the battery controller, a connection indication signal associated with the given battery in response to the battery connection condition being satisfied; transmitting, by the battery controller, the connection indication signal and battery identification information associated with the given battery to a battery stack controller using a wired communication protocol; transmitting, by the battery stack controller, the connection indication signal and the battery identification information to a central controller using a wireless communication protocol; monitoring, by the central controller, a location of the given battery based on the connection indication signal and the battery identification information; and controlling, by the central controller, an operation of a robot based on the location of the given battery.

The following paragraph includes variations of the method of the above paragraph, and the variations may be implemented individually or in any combination.

In one form, the battery connection condition is satisfied in response to a connector of the given battery being coupled to an additional connector; the additional connector is disposed at one of an additional battery from among the plurality of batteries and a charging station; the connector includes a plurality of general-purpose input/output (GPIO) pins, a plurality of transmission pins, and a plurality of reception pins, and where the battery connection condition is satisfied in response to the plurality of GPIO pins being physically coupled to the additional connector; the given battery, the battery controller, and the battery stack controller are communicably coupled via the wired communication protocol, and where the wired communication protocol includes a universal asynchronous receiver/transmitter (UART) protocol, an inter-integrated circuits (I2C) protocol, a serial peripheral interface (SPI) protocol, or a combination thereof; the battery stack controller and the central controller are communicably coupled via the wireless communication protocol, and where the wireless communication protocol includes one of a message queuing telemetry transport (MQTT) protocol and an ultra-wideband (UWB) protocol; the connection indication signal is a connection timestamp, and where monitoring the location of the given battery based on the connection timestamp and the battery identification information further comprises: storing, by the central controller, the battery identification information and the connection timestamp as a database entry of a battery location database, and where the method further comprises determining, by the battery controller and in response to generating the database entry, whether a battery disconnection condition of the given battery is satisfied, and updating, by the central controller and in response to the battery disconnection condition being satisfied, the database entry to include a disconnection timestamp and the battery identification information, where the location is based on the connection timestamp and the disconnection timestamp; and/or where controlling the operation of the robot based on the location of the given battery further comprises autonomously navigating the robot to retrieve the given battery.

The present disclosure provides a system comprising a plurality of batteries disposed within a battery stack, a battery controller communicably coupled to a given battery from among the plurality of batteries, a battery stack controller communicably coupled to the battery controller via a wired communication protocol, and a central controller communicably coupled to the battery stack controller via a wireless communication protocol. The battery controller is configured to determine whether a battery connection condition of the given battery is satisfied, the battery controller is configured to generate a connection timestamp associated with the given battery in response to the battery connection condition being satisfied, and the battery controller is configured to transmit the connection timestamp and battery identification information associated with the given battery to the battery stack controller. The battery stack controller is configured to transmit the connection timestamp and the battery identification information to the central controller, the central controller is configured to monitor a location of the given battery based on the connection timestamp and the battery identification information, and the central controller is configured to control an operation of a robot based on the location of the given battery.

The following paragraph includes variations of the system of the above paragraph, and the variations may be implemented individually or in any combination.

In one form, the battery connection condition is satisfied in response to a connector of the given battery being coupled to an additional connector; the additional connector is disposed at one of an additional battery from among the plurality of batteries and a charging station; the connector includes a plurality of general-purpose input/output (GPIO) pins, a plurality of transmission pins, and a plurality of reception pins, and where the battery connection condition is satisfied in response to the plurality of GPIO pins being physically coupled to the additional connector; the wired communication protocol includes a universal asynchronous receiver/transmitter (UART) protocol, an inter-integrated circuits (I2C) protocol, a serial peripheral interface (SPI) protocol, or a combination thereof; the wireless communication protocol includes one of a message queuing telemetry transport (MQTT) protocol and an ultra-wideband (UWB) protocol; the central controller is configured to store the battery identification information and the connection timestamp as a database entry of a battery location database; the battery controller is configured to determine, in response to generating the database entry, whether a battery disconnection condition of the given battery is satisfied; the central controller is configured to update, in response to the battery disconnection condition being satisfied, the database entry to include a disconnection timestamp and the battery identification information; and the location is based on the connection timestamp and the disconnection timestamp; and/or controlling the operation of the robot based on the location of the given battery further comprises autonomously navigating the robot to retrieve the given battery.

The present disclosure provides a method including determining, by a battery controller, whether a battery connection condition of a given battery from among a plurality of batteries disposed within a battery stack is satisfied, where the battery connection condition is satisfied in response to a connector of the given battery being coupled to an additional connector disposed at one of an additional battery from among the plurality of batteries and a charging station, the connector includes a plurality of general-purpose input/output (GPIO) pins, a plurality of transmission pins, and a plurality of reception pins, and the battery connection condition is satisfied in response to the plurality of GPIO pins being physically coupled to the additional connector. The method includes generating, by the battery controller, a connection timestamp associated with the given battery in response to the battery connection condition being satisfied, transmitting, by the battery controller, the connection timestamp and battery identification information associated with the given battery to a battery stack controller using a wired communication protocol, and transmitting, by the battery stack controller, the connection timestamp and the battery identification information to a central controller using a wireless communication protocol. The method includes monitoring, by the central controller, the location of the given battery based on the connection timestamp, the battery identification information and a battery identification model, and controlling, by the central controller, an operation of a robot based on the location of the given battery.

The following paragraph includes variations of the method of the above paragraph, and the variations may be implemented individually or in any combination.

In one form, the given battery, the battery controller, and the battery stack controller are communicably coupled via the wired communication protocol, and where the wired communication protocol includes a universal asynchronous receiver/transmitter (UART) protocol, an inter-integrated circuits (I2C) protocol, a serial peripheral interface (SPI) protocol, or a combination thereof; the battery stack controller and the central controller are communicably coupled via the wireless communication protocol, and where the wireless communication protocol includes one of a message queuing telemetry transport (MQTT) protocol and an ultra-wideband (UWB) protocol; and/or monitoring the location of the given battery based on the connection timestamp and the battery identification information further comprises storing, by the central controller, the battery identification information and the connection timestamp as a database entry of a battery location database, and where the method further comprises determining, by the battery controller and in response to generating the database entry, whether a battery disconnection condition of the given battery is satisfied, updating, by the central controller and in response to the battery disconnection condition being satisfied, the database entry to include a disconnection timestamp and the battery identification information, where the location is based on the connection timestamp and the disconnection timestamp.

Further areas of applicability will become apparent from the description provided herein. It should be understood that the description and specific examples are intended for purposes of illustration only and are not intended to limit the scope of the present disclosure.

### DRAWINGS

In order that the disclosure may be well understood, there will now be described various forms thereof, given by way of example, reference being made to the accompanying drawings, in which:

FIG. 1 is a functional block diagram of a manufacturing environment in accordance with the teachings of the present disclosure;

FIG. 2A schematically illustrates a connector disposed at a battery in accordance with the teachings of the present disclosure;

FIG. 2B schematically illustrates a connector disposed at a battery in accordance with the teachings of the present disclosure; and

FIG. 3 is a flowchart illustrating an example routine for localizing a battery in a battery stack in accordance with the teachings of the present disclosure.

The drawings described herein are for illustration purposes only and are not intended to limit the scope of the present disclosure in any way.

### DETAILED DESCRIPTION

The following description is merely exemplary in nature and is not intended to limit the present disclosure, application, or uses. It should be understood that throughout the drawings, corresponding reference numerals indicate like or corresponding parts and features.

The present disclosure provides a plurality of battery controllers, a plurality of battery stack controllers, and a central controller that collaboratively localize a battery within a battery stack. Specifically, the controllers collectively monitor the presence of battery connections and disconnections along with information identifying the battery to thereby precisely and accurately locate the battery. As such, the controllers may perform various responsive actions with improved accuracy and inhibited latency, such as controlling one or more robots to retrieve a battery from or deposit a battery at a given location within a manufacturing environment.

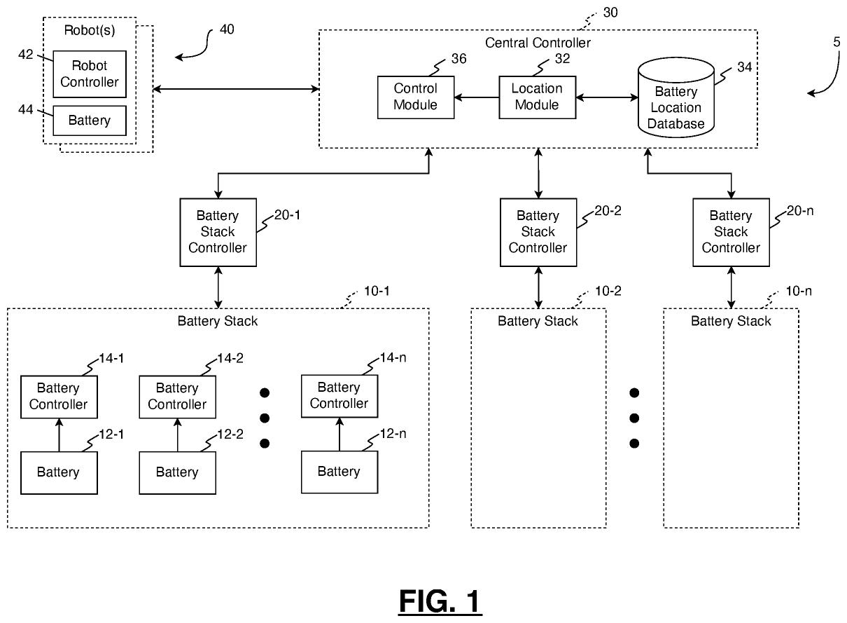

Referring to FIG. 1, a manufacturing environment 5 is shown and generally includes battery stacks 10-1, 10-2, . . . 10-n (collectively referred to hereinafter as “battery stacks 10”), battery stack controllers 20-1, 20-2, . . . 20-n (collectively referred to hereinafter as “battery stack controllers 20”), a central controller 30, and a plurality of robots 40. As described below in further detail, the battery stack controllers 20, the central controller 30, and the robots 40 are communicably coupled using a wired and/or wireless communication protocol.

In one form, the robots 40 are mobile robots or automated guided vehicles that are partially or fully autonomous and are configured to move to various locations of the manufacturing environment 5, as instructed by the central controller 30. To autonomously move itself, a robot controller 42 is configured to control various movement systems of the robot 40 (e.g., propulsion systems, steering systems, and/or brake systems) via actuators, one or more batteries 44, and based on data one or more navigation sensors of the robot 40 (e.g., a global navigation satellite system (GNSS) sensor, an image sensor, a local position sensor, among others). Furthermore, the robot controller 42 is configured to operate the actuators to control the motion of one or more robotic links (e.g., robotic arms) attached thereto and thereby perform one or more automated tasks. The one or more automated tasks may refer to one or more motions the robot 40 performs to achieve a desired result, such as removing the battery 44 from the robot 40 and positioning it within one of the battery stacks 10, retrieving and connecting a battery from one of the battery stacks 10, removing an unfinished workpiece from a bin, loading an unfinished or semi-finished workpiece into a fixture, transporting a payload from one location to another, among others.

In one form, the battery stacks 10 each include batteries 12-1, 12-2, . . . 12-n (collectively referred to hereinafter as “batteries 12”) and battery controllers 14-1, 14-2, . . . 14-n (collectively referred to hereinafter as “battery controllers 14”). The battery stacks 10 may each include an enclosure that provides a structural surrounding and sealed compartment for the batteries 12 and other battery components, such as cooling lines, support brackets, wiring disposed therein or extending therethrough, lids, body, and/or a seal. Additionally, the battery stacks 10 may include a structural assembly surrounding the batteries 12, where each structural assembly is a modular structure that can be installed and removed within the enclosure. Example enclosures, battery components, structural assemblies, and the arrangements thereof are disclosed in U.S. patent Ser. No. 17/980,207 titled “STRUCTURAL ASSEMBLY FOR BATTERY STRUCTURE OF ELECTRIC VEHICLE,” which is commonly owned with the present application and the contents of which are incorporated herein by reference in its entirety.

In one form, the batteries 12 are arranged in a battery array (e.g., a side-by-side configuration, a vertical configuration, among other array configurations) and are rechargeable by an alternating current (AC) power supply system, a direct current (DC) power supply system, or a combination thereof (not shown). As an example, the batteries 12 are provided by lithium-ion batteries, such as those in which the cell components are enclosed in an aluminum-coated plastic film, or any other suitable electrical power storage units.

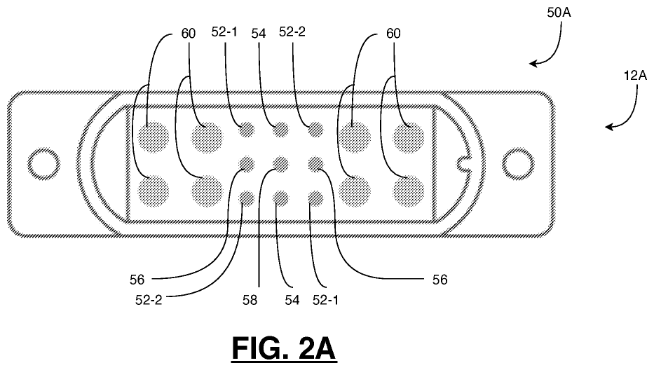

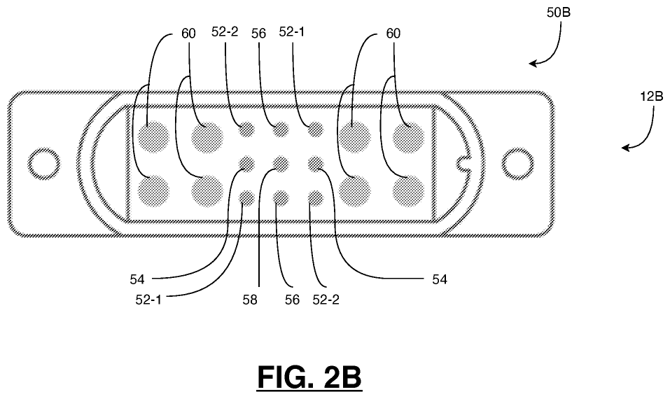

In one form, the battery controllers 14 are configured to determine whether a battery connection condition or a battery disconnection condition is satisfied for one of the batteries 12. The battery connection condition may be satisfied in response to a connector of one of the batteries 12 being connected to an additional connector disposed at another battery 12 within the stack 10 or a charging station (e.g., a battery charging station disposed at an infrastructure element or movable element within the manufacturing environment 5). As an example, and as shown in FIGS. 2A-2B, each battery 12 may include a first connector 50A disposed at first end 12A of the battery 12 and a second connector 50B disposed at a second and opposing end 12B of the battery 12. The first connector 50A and the second connector 50B may be collectively referred to hereinafter as “connectors 50.” Each of the connectors 50 includes a plurality of general-purpose input/output (GPIO) input pins 52-1, a plurality of GPIO output pins 52-2 (collectively referred to hereinafter as “GPIO” pins 52), a plurality of transmission pins 54, a plurality of reception pins 56, a grounding pin 58 for electrically grounding the connectors 50, and auxiliary pins 60. In some forms, the connectors 50 may be rotationally invariant to thereby facilitate connections and disconnections among the plurality of batteries 12 within the battery stack 10.

As an example, the battery connection condition may be satisfied when a first connector 50A of the battery 12-1 is connected to a second connector 50B of the battery 12-2, and the battery disconnection condition may be satisfied when the first connector 50A of the battery 12-1 is disconnected from the second connector 50B of the battery 12-2. That is, the battery controllers 14 are configured to determine whether the battery connection condition or the battery disconnection condition is satisfied based on one or more signals detected via the GPIO pins 52.

In one form, the battery controller 14 generates a connection indication signal in response to one of the batteries 12 of the battery stack 10 satisfying the battery connection condition and provides the connection indication signal to the battery stack controller 20. Furthermore, the battery controller 14 may generate a disconnection indication signal in response to one of the batteries 12 of the battery stack 10 satisfying the battery disconnection condition and provides the disconnection indication signal to the battery stack controller 20.

To perform the functionality described herein, the batteries 12, the battery controllers 14, and the battery stack controllers 20 are communicably coupled via a wired communication protocol, such as a universal asynchronous receiver/transmitter (UART) protocol, an inter-integrated circuits (I2C) protocol, a serial peripheral interface (SPI) protocol, or a combination thereof. That is, the batteries 12 are coupled to the battery controllers 14 via the transmission pins 54 and the reception pins 56, and the battery controllers 14 are coupled to the battery stack controller 20 via a similar wired communication protocol. As such, latency associated with detecting whether the battery connection condition or disconnection condition is satisfied are inhibited. It should be understood that other wired communication protocols may be employed and are not limited to the examples described herein.

In response to receiving the connection or disconnection indication signal, the battery stack controller 20 is configured to transmit the respective connection/disconnection indication signal to the central controller 30. In one form, the connection indication signal is a connection timestamp associated with a time in which the connection of the battery 12 is completed. Furthermore, the disconnection indication signal may be a disconnection timestamp associated with a time in which the disconnection of the given battery 12 from the battery stack 10 is completed. Along with the connection/disconnection indication signal, the battery stack controller 20 may transmit battery identification information that uniquely identifies the one or more batteries 12 associated with the connection/disconnection indication signal (e.g., a unique string of characters identifying the battery 12).

In one form, each battery stack controller 20 is associated with a given battery stack 10, the battery stack controller 20 may transmit battery stack controller identification signal that uniquely identifies the battery stack controller 20. As described below in further detail, the central controller 30 may determine the location of the batteries 12 based on the battery stack controller identification signal. In one form, the battery stack controllers 20 are communicably coupled to the central controller 30 via a wireless communication protocol, such as a message queuing telemetry transport (MQTT) protocol or an ultra-wideband (UWB) protocol.

In one form, the central controller 30 includes a location module 32, a battery location database 34, and a control module 36. The location module 32 is configured to monitor a location of the batteries 12 based on the connection indication signals and the battery identification information received from the battery stack controllers 20. As an example, the location module 32 stores the battery identification information and the connection timestamps (as the connection indication signal) associated with the connection indication signals received from the battery stack controllers 20 as entries in the battery location database 34. The location module 32 determines whether a subsequent disconnection indication signal is received having battery identification information associated with one of the entries stored in the battery location database 34. In response to the subsequent disconnection indication signal being received, the location module 32 updates the respective entry from the battery location database 34 and stores a disconnection timestamp associated with the disconnection indication signal.

Accordingly, the location module 32 is configured to determine the location of the battery 12 based on the connection timestamp and the disconnection timestamp and the battery stack controller identification signals broadcasted by the battery stack controllers 20. Specifically, by monitoring consecutive connection timestamps and disconnection timestamps of a given entry in the battery location database 34 and changes in the battery stack controller identification signals, the location module 32 can accurately track the location of the batteries 12 as they are removed from given battery stacks 10, coupled to one of the robots 40, and disposed at different battery stacks 10 when, for example, a charging operation is performed on one of the batteries 12 at a charging station.

The control module 36 is configured to control the operation of the robots 40 based on the location of the given batteries 12 determined by the location module 32. As an example, the control module 36 instructs the robots 40 to autonomously navigate to a location associated with a given battery 12 by generating and transmitting a planned path to the robot controller 42 and instructing the robot 40 to travel to the destination based on the planned path to retrieve the battery 12. As another example, the control module 36 remotely and autonomously controls the robots 40 to travel to a charging station within the manufacturing environment 5 to thereby deposit an onboard battery 44. To control the autonomous movement of the robot 40, the control module 36 and/or the robot 40 may employ known autonomous navigation routines, such as a path planning routine, a maneuver planning routine, and/or a trajectory planning routine.

To perform the functionality described herein, the battery controllers 14, the battery stack controllers 20, the central controller 30, and the robot controllers 42 may each include one or more processor circuits that are configured to execute machine-readable instructions stored in one or more nontransitory computer-readable mediums, such as a random-access memory (RAM) circuit and/or read-only memory (ROM) circuit. The one or more robots 40 may also include other components for performing the operations described herein, such as movement drivers and systems, transceivers, routers, and/or input/output interface hardware.

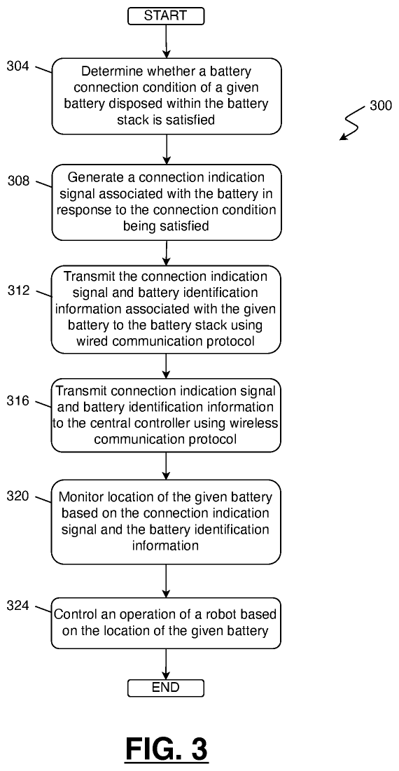

Referring to FIG. 3, a flowchart illustrating a routine 300 for localizing a battery 12 in the battery stack 10 is shown. At 304, the battery controller 14 determines whether a battery connection condition of a given battery 12 disposed within the battery stack 10 is satisfied. At 308, the battery controller 14 generates a connection indication signal associated with the given battery 12 in response to the battery connection condition being satisfied. At 312, the battery controller 14 transmits the connection indication signal and battery identification information associated with the given battery 12 to the battery stack controller 20 using a wired communication protocol. At 316, the battery stack controller 20 transmits the connection indication signal and the battery identification information to the central controller 30 using a wireless communication protocol. At 320, the central controller 30 monitors a location of the given battery 12 based on the connection indication signal and the battery identification information. At 324, the central controller 30 controls an operation of one or more of the robots 40 based on the location of the given battery.

Unless otherwise expressly indicated herein, all numerical values indicating mechanical/thermal properties, compositional percentages, dimensions and/or tolerances, or other characteristics are to be understood as modified by the word “about” or “approximately” in describing the scope of the present disclosure. This modification is desired for various reasons including industrial practice, material, manufacturing, and assembly tolerances, and testing capability.

As used herein, the phrase at least one of A, B, and C should be construed to mean a logical (A OR B OR C), using a non-exclusive logical OR, and should not be construed to mean “at least one of A, at least one of B, and at least one of C.”

In this application, the term “controller” and/or “module” may refer to, be part of, or include: an Application Specific Integrated Circuit (ASIC); a digital, analog, or mixed analog/digital discrete circuit; a digital, analog, or mixed analog/digital integrated circuit; a combinational logic circuit; a field programmable gate array (FPGA); a processor circuit (shared, dedicated, or group) that executes code; a memory circuit (shared, dedicated, or group) that stores code executed by the processor circuit; other suitable hardware components (e.g., op amp circuit integrator as part of the heat flux data module) that provide the described functionality; or a combination of some or all of the above, such as in a system-on-chip.

The term memory is a subset of the term computer-readable medium. The term computer-readable medium, as used herein, does not encompass transitory electrical or electromagnetic signals propagating through a medium (such as on a carrier wave); the term computer-readable medium may therefore be considered tangible and non-transitory. Non-limiting examples of a non-transitory, tangible computer-readable medium are nonvolatile memory circuits (such as a flash memory circuit, an erasable programmable read-only memory circuit, or a mask read-only circuit), volatile memory circuits (such as a static random access memory circuit or a dynamic random access memory circuit), magnetic storage media (such as an analog or digital magnetic tape or a hard disk drive), and optical storage media (such as a CD, a DVD, or a Blu-ray Disc).

The apparatuses and methods described in this application may be partially or fully implemented by a special purpose computer created by configuring a general-purpose computer to execute one or more particular functions embodied in computer programs. The functional blocks, flowchart components, and other elements described above serve as software specifications, which can be translated into the computer programs by the routine work of a skilled technician or programmer.

The description of the disclosure is merely exemplary in nature and, thus, variations that do not depart from the substance of the disclosure are intended to be within the scope of the disclosure. Such variations are not to be regarded as a departure from the spirit and scope of the disclosure.

What is claimed is:

1. A method comprising:
determining, by a battery controller, whether a battery connection condition of a given battery from among a plurality of batteries disposed within a battery stack is satisfied;
generating, by the battery controller, a connection indication signal associated with the given battery in response to the battery connection condition being satisfied;
transmitting, by the battery controller, the connection indication signal and battery identification information associated with the given battery to a battery stack controller using a wired communication protocol;
transmitting, by the battery stack controller, the connection indication signal and the battery identification information to a central controller using a wireless communication protocol;
monitoring, by the central controller, a location of the given battery based on the connection indication signal and the battery identification information; and
controlling, by the central controller, an operation of a robot based on the location of the given battery.

2. The method of claim 1, wherein the battery connection condition is satisfied in response to a connector of the given battery being coupled to an additional connector.

3. The method of claim 2, wherein the additional connector is disposed at one of an additional battery from among the plurality of batteries and a charging station.

4. The method of claim 2, wherein the connector includes a plurality of general-purpose input/output (GPIO) pins, a plurality of transmission pins, and a plurality of reception pins, and wherein the battery connection condition is satisfied in response to the plurality of GPIO pins being physically coupled to the additional connector.

5. The method of claim 1, wherein the given battery, the battery controller, and the battery stack controller are communicably coupled via the wired communication protocol, and wherein the wired communication protocol includes a universal asynchronous receiver/transmitter (UART) protocol, an inter-integrated circuits (I2C) protocol, a serial peripheral interface (SPI) protocol, or a combination thereof.

6. The method of claim 1, wherein the battery stack controller and the central controller are communicably coupled via the wireless communication protocol, and wherein the wireless communication protocol includes one of a message queuing telemetry transport (MQTT) protocol and an ultra-wideband (UWB) protocol.

7. The method of claim 1, wherein the connection indication signal is a connection timestamp, wherein monitoring the location of the given battery based on the connection timestamp and the battery identification information further comprises storing, by the central controller, the battery identification information and the connection timestamp as a database entry of a battery location database, and wherein the method further comprises:
determining, by the battery controller and in response to generating the database entry, whether a battery disconnection condition of the given battery is satisfied; and
updating, by the central controller and in response to the battery disconnection condition being satisfied, the database entry to include a disconnection timestamp and the battery identification information, wherein the location is based on the connection timestamp and the disconnection timestamp.

8. The method of claim 1, wherein controlling the operation of the robot based on the location of the given battery further comprises autonomously navigating the robot to retrieve the given battery.

9. A system comprising:
a plurality of batteries disposed within a battery stack;
a battery controller communicably coupled to a given battery from among the plurality of batteries;
a battery stack controller communicably coupled to the battery controller via a wired communication protocol; and
a central controller communicably coupled to the battery stack controller via a wireless communication protocol, wherein:
the battery controller is configured to determine whether a battery connection condition of the given battery is satisfied;
the battery controller is configured to generate a connection timestamp associated with the given battery in response to the battery connection condition being satisfied;
the battery controller is configured to transmit the connection timestamp and battery identification information associated with the given battery to the battery stack controller;
the battery stack controller is configured to transmit the connection timestamp and the battery identification information to the central controller;
the central controller is configured to monitor a location of the given battery based on the connection timestamp and the battery identification information; and
the central controller is configured to control an operation of a robot based on the location of the given battery.

10. The system of claim 9, wherein the battery connection condition is satisfied in response to a connector of the given battery being coupled to an additional connector.

11. The system of claim 10, wherein the additional connector is disposed at one of an additional battery from among the plurality of batteries and a charging station.

12. The system of claim 10, wherein the connector includes a plurality of general-purpose input/output (GPIO) pins, a plurality of transmission pins, and a plurality of reception pins, and wherein the battery connection condition is satisfied in response to the plurality of GPIO pins being physically coupled to the additional connector.

13. The system of claim 9, wherein the wired communication protocol includes a universal asynchronous receiver/transmitter (UART) protocol, an inter-integrated circuits (I2C) protocol, a serial peripheral interface (SPI) protocol, or a combination thereof.

14. The system of claim 9, wherein the wireless communication protocol includes one of a message queuing telemetry transport (MQTT) protocol and an ultra-wideband (UWB) protocol.

15. The system of claim 9, wherein:
the central controller is configured to store the battery identification information and the connection timestamp as a database entry of a battery location database;
the battery controller is configured to determine, in response to generating the database entry, whether a battery disconnection condition of the given battery is satisfied;
the central controller is configured to update, in response to the battery disconnection condition being satisfied, the database entry to include a disconnection timestamp and the battery identification information; and
the location is based on the connection timestamp and the disconnection timestamp.

16. The system of claim 9, wherein controlling the operation of the robot based on the location of the given battery further comprises autonomously navigating the robot to retrieve the given battery.

17. A method comprising:
determining, by a battery controller, whether a battery connection condition of a given battery from among a plurality of batteries disposed within a battery stack is satisfied, wherein:
the battery connection condition is satisfied in response to a connector of the given battery being coupled to an additional connector disposed at one of an additional battery from among the plurality of batteries and a charging station;
the connector includes a plurality of general-purpose input/output (GPIO) pins, a plurality of transmission pins, and a plurality of reception pins; and
the battery connection condition is satisfied in response to the plurality of GPIO pins being physically coupled to the additional connector;
generating, by the battery controller, a connection timestamp associated with the given battery in response to the battery connection condition being satisfied;
transmitting, by the battery controller, the connection timestamp and battery identification information associated with the given battery to a battery stack controller using a wired communication protocol;
transmitting, by the battery stack controller, the connection timestamp and the battery identification information to a central controller using a wireless communication protocol;
monitoring, by the central controller, a location of the given battery based on the connection timestamp, the battery identification information and a battery identification model; and
controlling, by the central controller, an operation of a robot based on the location of the given battery.

18. The method of claim 17, wherein the given battery, the battery controller, and the battery stack controller are communicably coupled via the wired communication protocol, and wherein the wired communication protocol includes a universal asynchronous receiver/transmitter (UART) protocol, an inter-integrated circuits (I2C) protocol, a serial peripheral interface (SPI) protocol, or a combination thereof.

19. The method of claim 17, wherein the battery stack controller and the central controller are communicably coupled via the wireless communication protocol, and wherein the wireless communication protocol includes one of a message queuing telemetry transport (MQTT) protocol and an ultra-wideband (UWB) protocol.

20. The method of claim 17, wherein monitoring the location of the given battery based on the connection timestamp and the battery identification information further comprises storing, by the central controller, the battery identification information and the connection timestamp as a database entry of a battery location database, and wherein the method further comprises:
determining, by the battery controller and in response to generating the database entry, whether a battery disconnection condition of the given battery is satisfied; and
updating, by the central controller and in response to the battery disconnection condition being satisfied, the database entry to include a disconnection timestamp and the battery identification information, wherein the location is based on the connection timestamp and the disconnection timestamp.
